(19) United States
(12) Patent Application Publication
(10) Pub. No.: US 2025/0221073 A1
(43) Pub. Date: Jul. 3, 2025

(54) HIGH DNAMIC RANGE OPTICAL SENSOR USING TRENCH CAPACITORS WITH SIDEWALL STRUCTURES

(71) Applicant: SEMICONDUCTOR COMPONENTS INDUSTRIES, LLC, Scottsdale, AZ (US)

(72) Inventors: Vladimir KOROBOV, San Mateo, CA (US); Swarnal BORTHAKUR, Boise, ID (US)

(73) Assignee: SEMICONDUCTOR COMPONENTS INDUSTRIES, LLC, Scottsdale, AZ (US)

(21) Appl. No.: 18/397,847

(22) Filed: Dec. 27, 2023

(51) Int. Cl. H01L 27/146; H04N 25/57

(52) U.S. Cl. CPC H10F 39/8063; H04N 25/57; H10F 39/024; H10F 39/8053; H10F 39/807; H10F 39/811

(57) ABSTRACT

An optical sensor and included pixel circuits of an array of pixel circuits are described. Each pixel circuit may include a microlens, a color filter disposed adjacent the microlens, and an epitaxial substrate layer disposed adjacent the color filter opposite the microlens. An isolation trench may be formed in the epitaxial substrate layer to provide a trench capacitor for the pixel circuit, and having sidewalls with sidewall recesses formed therein that increase a surface area, and therefore a capacitance, of the trench capacitor.

### TECHNICAL FIELD

This description relates to high dynamic range (HDR) sensors.

### BACKGROUND

Many devices, such as cellular telephones, cameras, and computers, commonly use optical sensors, such as image sensors. For example, a typical imager sensor may include a focal plane array of pixels, where each pixel includes a photosensor, such as a photogate, photoconductor, or photodiode, for accumulating photo-generated charge in a portion of an underlying substrate. When photons impinge on the photosensor, electron-hole pairs are generated. Conventional image sensors convert the electrons that are collected in the pixels into a voltage, while the holes are generally discarded into the substrate.

High Dynamic Range (HDR), in the context of image sensing, generally refers to a ratio of a highest detectable illumination level to a lowest detectable illumination level. For example, an HDR image sensor is capable of imaging a scene that includes both bright and dark portions. When an imaged scene includes portions that are beyond an illumination level detectable by an image sensor being used, then the image sensor may saturate, resulting, for example, in areas of uniform brightness within a captured image that do not accurately reflect actual levels of brightness in the captured scene.

### SUMMARY

Described techniques increase a per-pixel capacitance of an optical sensor through the use of deep trench capacitors with sidewall structures, such as sidewall scallops. As a result, a dynamic range of the optical sensor may be improved.

According to one general aspect, a semiconductor device includes a microlens, a color filter disposed adjacent the microlens, an epitaxial substrate layer disposed adjacent the color filter opposite the microlens, and a trench capacitor formed in the epitaxial substrate layer and having sidewall recesses.

According to another general aspect, an optical sensor including an array of pixel circuits, each pixel circuit comprising a microlens, a color filter disposed adjacent the microlens, an epitaxial substrate layer disposed adjacent the color filter opposite the microlens, and an isolation trench formed in the epitaxial substrate layer and having sidewalls with sidewall recesses formed therein, the sidewall recesses having insulating material disposed therein and the isolation trench having a conductive material disposed therein.

According to another general aspect, a method of making a semiconductor device includes forming a trench in an epitaxial substrate layer, the trench having sidewall recesses, providing an insulating material in the sidewall recesses, and providing a conductive material in the trench adjacent to the insulating material. The method includes providing a color filter adjacent to a surface of the epitaxial substrate layer, and forming a microlens adjacent to the color filter.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an example implementation of a high dynamic range (HDR) optical sensor with trench capacitors having sidewall structures.

FIG. 2 is a first alternate example of the HDR image sensor of FIG. 1.

FIG. 3 is a second alternate example of the HDR image sensor of FIG. 1.

FIG. 4 is an isometric view of example pixels of the HDR image sensors of FIGS. 1-3.

FIG. 5 is an example top view of the pixels of FIG. 4 with a deep trench capacitor on two walls of each pixel.

FIG. 6A is a first example top view of the pixels of FIG. 4 with separate deep trench capacitors on each of two walls of each pixel.

FIG. 6B is a second example top view of the pixels of FIG. 4 with separate deep trench capacitors on each of two walls of each pixel.

FIG. 7 illustrates first example operations of an example process flow for manufacturing the image sensors of FIGS. 1-6.

FIG. 8 illustrates second example operations of an example process flow for manufacturing the image sensors of FIGS. 1-6.

FIG. 9 illustrates third example operations of an example process flow for manufacturing the image sensors of FIGS. 1-6.

FIG. 10 illustrates fourth example operations of an example process flow for manufacturing the image sensors of FIGS. 1-6.

FIG. 11 illustrates fifth example operations of an example process flow for manufacturing the image sensors of FIGS. 1-6.

FIG. 12 illustrates sixth example operations of an example process flow for manufacturing the image sensors of FIGS. 1-6.

FIG. 13 illustrates seventh example operations of an example process flow for manufacturing the image sensors of FIGS. 1-6.

FIG. 14 illustrates eighth example operations of an example process flow for manufacturing the image sensors of FIGS. 1-6.

FIG. 15 is a flowchart illustrating example operations for manufacturing the image sensors of FIGS. 1-6, corresponding to the example operations of FIGS. 7-14.

FIG. 16 is a graph illustrating examples of capacitance per pixel versus dielectric thickness for example embodiments.

FIG. 17 is a graph illustrating examples of capacitance per pixel versus trench depth for example embodiments.

### DETAILED DESCRIPTION

Described techniques increase a per-pixel capacitance of an optical sensor through the use of deep trench capacitors with sidewall structures, such as scallops. The sidewall structures increase a surface area of each of the deep trench capacitors, relative to conventional optical sensor capacitors, so that each capacitor may hold relatively more charge. Consequently, resulting optical sensors have a higher dynamic range than conventional optical sensors that use capacitors with no sidewall structures.

In some examples, trenches of described deep trench capacitors with sidewall structures may be formed (may extend) through an entire depth of an optical sensor substrate. In other examples, the trenches of described deep trench capacitors with sidewall structures may extend only partially through the optical sensor substrate.

Described sidewall structures of pixel capacitors may be formed using any suitable technique. For example, sidewall scallops may be formed using the Bosch process, which is a deep reactive ion etching (DRIE) process, or other suitable type of etching process.

Described capacitors with sidewall structures may be formed in multiple sides of each pixel of an optical sensor. For example, a capacitor may be formed in an L-shape around two sides of a pixel, or separate capacitors may be formed on each of two sides of a pixel. In additional or alternative examples, two or more capacitors may be formed on a single side of a pixel.

Thus, described devices and techniques for increasing a dynamic range of an optical sensor may provide improved pixel capacitance to allow for greater luminance range sensing. Described aspects may operate in conjunction with any suitable image capture system, such as a digital camera, a smartphone, a web camera, a video camera, a video surveillance system, or an automotive imaging system. Further, disclosed technology for the optical sensor may be utilized with any suitable imaging system, such as a camera system, video system, machine vision, vehicle navigation, surveillance system, motion detection system, and the like.

Described imaging systems may be configured to construct a digital HDR image using both low light level signals and high light level signals from a single exposure. For example, described image sensors may comprise arrays of pixel circuits to detect light and convey information that constitutes an image by converting the variable attenuation of a photon flow into electrical signals. Described image sensors may be implemented in conjunction with any appropriate technology, such as active pixel sensors in CMOS technology.

In various embodiments, an imaging system may comprise a primary lens to focus an image or scene onto an image sensor. For example, light may enter the imaging system through the primary lens and strike the image sensor. The image sensor may capture and generate image data corresponding to one or more rows in the array of pixel circuits. The image data may comprise image pixel data corresponding to one or more pixel circuits in the array of pixel circuits. For example, image data may comprise information representing a measured voltage, current, or other quantity as a result of light absorbed by each pixel circuit, such that each image pixel comprises an individual pixel intensity value.

The image sensor processes received image data according to any suitable functions such as demosaicing, white balancing, noise reduction, color correction, and the like. The image sensor may further comprise various signal processing circuits and/or systems, such as sample-and-hold circuitry, an analog-to-digital converter, an amplifier, and the like, used to convert the pixel charge to a digital image.

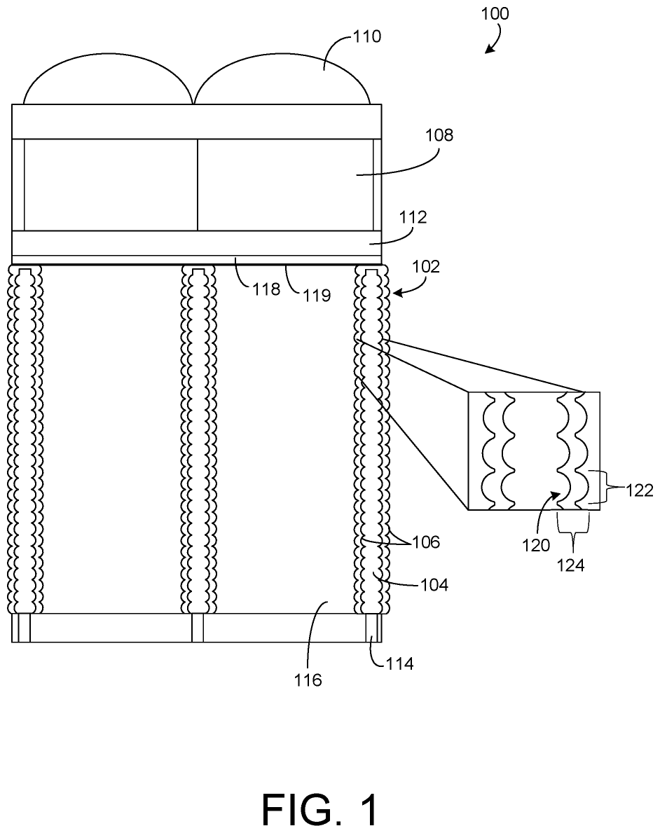

FIG. 1 illustrates an example implementation of a high dynamic range (HDR) optical sensor with trench capacitors 102 having sidewall structures 120. It will be appreciated that, in the following description, reference is primarily made to image sensor structures, but that example implementations may be provided for other types of optical sensors, as well.

As shown in FIG. 1, and described in detail, below, the sidewall structures 120 may be implemented as scallops, each scallop having a curvature that effectively increases a surface area, and thereby a capacitance, of the trench capacitors 102, relative to trench capacitors that do not have the sidewall structures 120.

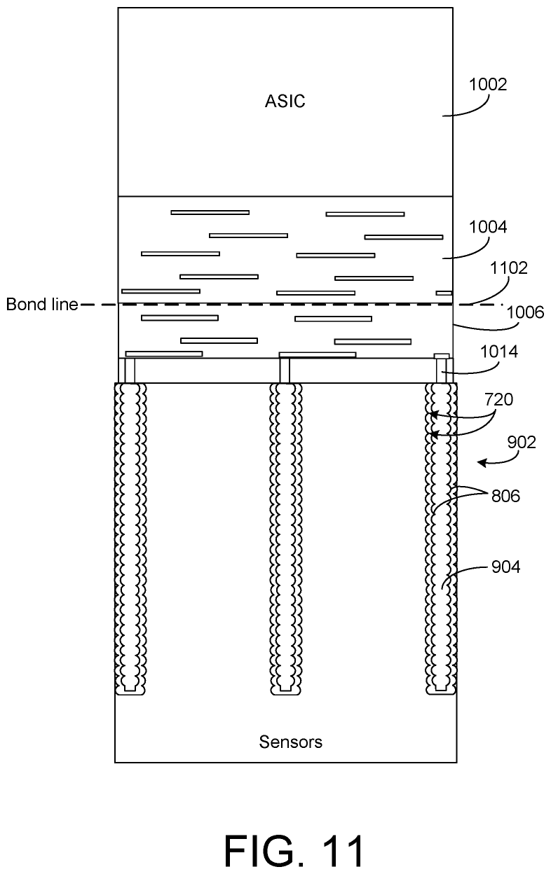

In FIG. 1, a pixel circuit 100 of an array of pixel circuits is configured to capture a portion of an image or scene. The pixel circuit 100 may be formed in the context of a first chip (for example, an image sensor chip) and a second chip (for example, an application specific integrated circuit (ASIC) chip) stacked vertically, as described in more detail below with respect to FIGS. 10 and 11. In the simplified example of FIG. 1, only relevant portions of an image sensor chip are illustrated, and a vertically stacked ASIC chip (or similar type of control chip) is omitted for the sake of clarity and brevity.

A solid-state pixel structure corresponding to a portion of the pixel circuit 100 includes an epitaxial substrate layer 116 having an upper surface covered with a silicon layer 112 (e.g. a passivation layer), formed of any suitable material such as silicon dioxide (SiO₂) or silicon nitride (Si₃N₄), to isolate and/or protect the epitaxial substrate layer 116.

As shown, and described in more detail, below, the sidewall structures 120 may be formed as recesses in the epitaxial substrate layer 116. The epitaxial substrate layer 116 may be further isolated by insulating layers 106 disposed along and within the sidewall structures 120, and a second oxide layer 118 disposed along the upper surface between the epitaxial substrate layer 116 and the silicon layer 112.

The pixel circuit 100 may further comprise a color filter 108 and a microlens 110. In example embodiments, a first side of the color filter 108 is disposed on an opposed side of the silicon layer 112 from the epitaxial substrate layer 116, as shown in FIG. 1. The microlens 110 is disposed adjacent to a second side of the color filter 108 that opposes the silicon layer 112. This arrangement is commonly referred to as a backside illuminated (BSI) image sensor pixel, as described below with respect to FIGS. 10-14. The microlens 110 concentrates impinging photons and generates electrons (and holes), which are collected in doped regions of the epitaxial substrate layer 116.

The trench capacitor 102, including a conductive material 104 and insulating layers 106, may thus be used to store the collected charge for further image processing. For example, the insulating layers 106 may be formed in the recesses of the sidewall structures 120. The trench capacitor 102 may be connected to a ground bias potential through a via 114.

The conductive material 104 may include any suitable conductive material, such as a doped polysilicon, copper, tungsten, or a transparent electrode such as indium tin oxide (ITO). The insulating layers 106 may comprise any suitable material for isolating the trench capacitor 102, including SiO₂, or may include a more advanced high k dielectric (HiK) material(s), such as halfnium oxide (HfOx), zirconium oxide (ZrOx), zirconium aluminate (ZrAlOx), tantalum pentoxide (Ta₂O₅), or aluminum oxide (Al₂O₃). An additional HiK layer 119 may be included between the epitaxial substrate layer 116 and the oxide layer 118, as shown.

In FIG. 1 and following embodiments, the vertical orientation of the trench capacitor 102 generally allows for a large charge storage capacity and high dynamic range without sacrificing a pixel area exposed to light. As a result, smaller sized pixels and higher quantum efficiency may be obtained, thereby providing improved sensor performance and lower cost.

In addition, as referenced above, the sidewall structures 120 provide increased surface area, which, other factors being equal, results in increased capacitance relative to trench capacitors without the sidewall structures 120. As shown in the exploded view of FIG. 1, the sidewall structures 120 may be formed as recesses in the epitaxial substrate layer 116, where each recess has a width 122 and a depth 124.

The sidewall structures 120 should be understood to describe any indentation or opening within sidewalls of the epitaxial substrate layer 116. For example, the sidewall structures 120 may represent concave surfaces that have been hollowed out or rounded inward with respect to the sidewalls of surrounding epitaxial substrate layer 116. The sidewall structures 120 may also be said to form convex surfaces with respect to peaks formed between pairs of recesses. Various other suitable terms may be used to describe the sidewall structures 120, such as indentations, cavities, or crenelations.

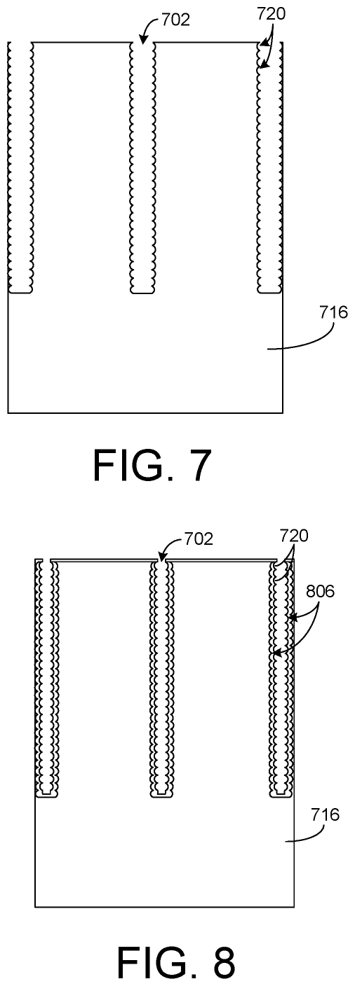

To provide the sidewall structures 120, a deep reactive ion etching (DRIE) process, such as the Bosch process, may be used. As illustrated below, with respect to FIG. 7, in the Bosch process, an initial opening in the epitaxial substrate layer 116 may be formed using any suitable technique, such as masking/etching. Then, the Bosch process may be implemented as a three-step processing cycle in which (1) a passivation layer is deposited within the opening on the exposed sidewalls and bottom of the opening, (2) a first etch is anisotropically executed to remove only a portion of the passivation layer between the sidewalls of the opening (that is, at the bottom of the opening), and thereby expose the epitaxial substrate layer 116 without removing the passivation layer from any previously-formed sidewall recesses, and (3) a second etch is isotropically executed to etch the exposed substrate at the bottom of the opening.

As the second etch isotropically etches the exposed substrate, new, individual ones of the various sidewall recesses 120 are formed. Repeating this three-step processing cycle multiple times (e.g., iterations, or loops) therefore results in progressive formation of the opening and associated sidewall recesses forming the sidewall structures 120, until a desired depth is reached for the trench capacitor 102 within the epitaxial substrate layer 116.

Using the type of DRIE processes referenced above, it is possible to form the trench capacitors 102 in a highly accurate and customized manner, while maintaining per-pixel consistency between corresponding capacitors of different pixels within the pixel circuit 100. That is, even though capacitance may be generally known to vary in direct proportion with surface area, conventional techniques for increasing surface area may be unsuitable for increasing the surface area of trench capacitors in the context of the pixel circuit 100, or similar pixel circuits.

For example, as just referenced, it may be desired to maintain per-pixel consistency between corresponding capacitors of difference pixels, in order to maintain overall image quality of captured images. For example, if capacitances of adjacent pixels vary, then one of the adjacent pixels may saturate at a different light level than the other of the adjacent pixels.

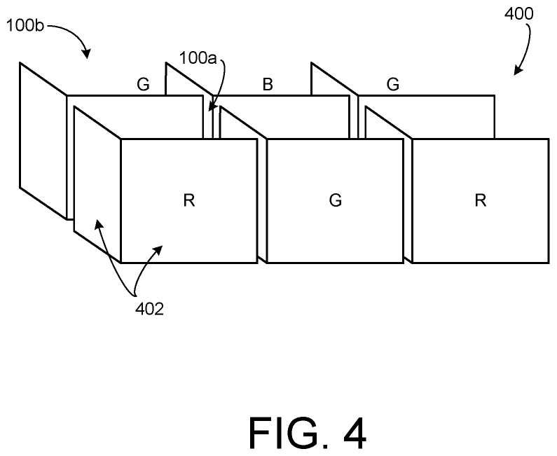

Using the types of DRIE processing described herein, the sidewall structures 120 may be formed consistently across corresponding capacitors of the various pixels of the pixel circuit 100. For example, as described with respect to FIGS. 4-6, each individual pixel of a pixel circuit may include two or more capacitors, and different ones of such intra-pixel capacitors may exhibit differences within the individual pixel with respect to one another, while inter-pixel capacitors have a common structure. In other words, pixels may have a common capacitor structure, which may include different types of capacitors within each pixel.

Described techniques may provide such inter-pixel capacitor consistency, while enabling a high degree of customization when constructing individual capacitors within each pixel. For example, a desired number, width, and depth of each of the trench capacitors 102 may easily be implemented, and the width 122 and depth 124 may also be tightly controlled, as described below with respect to FIG. 7.

For example, the DRIE process may be controlled by controlling various process parameters. For example, such process parameters may include gas flow rates for one or more of etching/deposition gasses, etching/deposition times, and/or processing power. As already mentioned, a total depth of the trench capacitors 102 may be determined by a total number of iterations of the three-step etching process that are completed, in conjunction with the various other relevant processing parameters.

In addition, such process parameters may be varied during the formation of the various instances of the trench capacitor 102, in order to obtain customized/desired aspects of the sidewall structures 120. For example, FIG. 1 illustrates the sidewall structures 120 as being identical to one another throughout a length of the trench capacitor 102. However, in example implementations, aspects of the sidewall structures may vary along the length of the trench capacitor 102.

For example, a first DRIE process may be implemented with first process parameters for a first number of iterations, to obtain sidewall structures 120 having first values for width 122 and/or depth 124. Then, a second DRIE process may be implemented with second process parameters for a second number of iterations, to obtain sidewall structures 120 having second values for width 122 and/or depth 124. Multiple such DRIE processes may be performed (for example, three or more) to obtain a desired trench capacitor structure. For example, sidewall structures 120 may be formed with a first set of sidewall structures with relatively small scallops (recesses) nearer the passivation layers 112, 118, and a second set of sidewall structures with relatively large scallops (recesses) nearer the vias 114. More generally, the sidewall structures 120 may be formed with “n” sets (for example, 3 or more) of sidewall structures with varying sizes of scallops (recesses) along a length of the trench capacitors 102.

In the example of FIG. 1, the trench capacitors 102 extend an entire distance through the epitaxial substrate layer 116. That is, the trench capacitors 102 extend between a lens-side surface of the epitaxial substrate layer 116 adjacent to the passivation layer 118 (also referred to as a backside of the image sensor) and an opposed surface of the epitaxial substrate layer 116 that is adjacent to the vias 114 (also referred to as a frontside of the image sensor). Put another way, the trench capacitors 102 may extend an entire distance of the epitaxial substrate layer 116 in a direction perpendicular to the color filter 108.

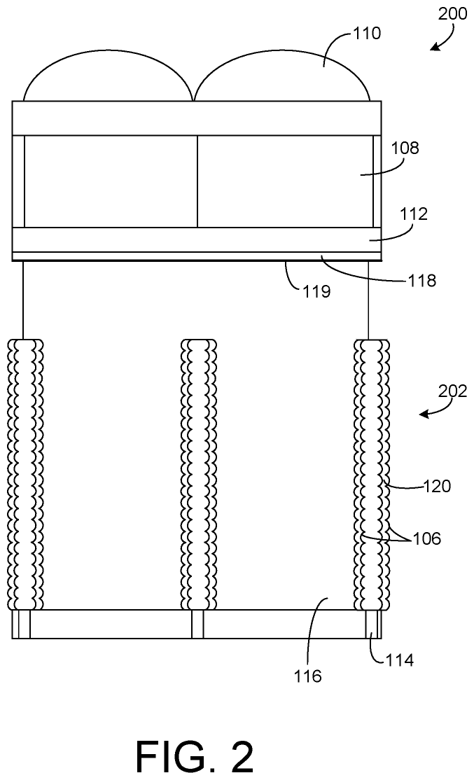

In other example implementations, however, trench capacitors may extend only partially through the epitaxial substrate layer 116. For example, FIG. 2 illustrates a pixel circuit 200, in which like elements have like reference numerals with respect to FIG. 1, and in which trench capacitors 202 extend only partially through the epitaxial substrate layer 116, from the frontside surface at the via 114 towards the backside surface in a direction of the color filter 108 and microlens 110.

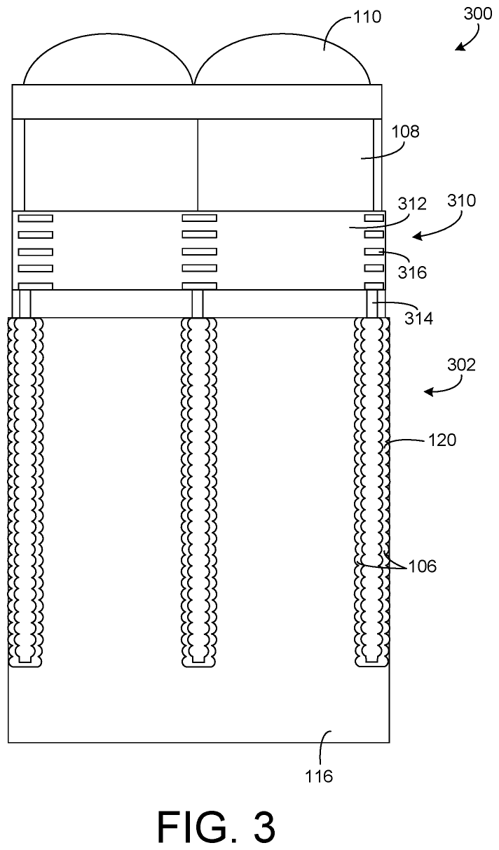

FIG. 3 illustrates another example implementation, in which a pixel circuit 300 includes trench capacitors 302 that extend partially through the epitaxial substrate layer 116. In FIG. 3, in contrast to the trench capacitors 202 in the example of FIG. 2, the trench capacitors 302 extend from a surface in a vicinity of the color filter 108 and the microlens 110 through the epitaxial substrate layer 116 in a direction of, but not reaching, the opposed surface of the epitaxial substrate layer 116.

In the example of FIG. 3, a metallization layer 310 is illustrated as being disposed between the trench capacitors 302 and the color filter 108. As further illustrated, the metallization layer 310 includes an interlayer dielectric layer 312, in which various metal layers 316 are formed. The trench capacitors 302 are connected to the metal layers 316 through a via 314, analogous to the via 114 of FIGS. 1 and 2. The example embodiment of FIG. 3 may be referred to as a frontside implementation, because impinging light travels through the metal layers 310 to reach the epitaxial substrate layer 116 and the trench capacitors 302.

FIG. 4 is an isometric view of example pixels of the HDR image sensors of FIGS. 1-3. FIG. 4 illustrates an array of pixel circuits 400, in which a first epitaxial substrate layer of a first pixel circuit 100a (as an example of the pixel circuit 100) may be isolated from a second epitaxial substrate layer of a second pixel circuit 100b by a deep trench isolation region(s) used to form the type of trench capacitor(s) 102 of FIG. 1.

In FIG. 4, trench capacitor(s) 402, analogous to the trench capacitor(s) 102 of FIG. 1, may be disposed along a given sidewall adjacent to a corresponding pixel circuit(s), such as the pixel circuits 100a, 100b. That is, conductive material disposed within trench isolation regions forms a capacitor surface used to form a capacitor for an adjacent photodetector of each pixel circuit 100a, 100b.

With reference to FIGS. 1-4, an overall capacitance of a given pixel circuit 100 (such as 100a, 100b of FIG. 4) may be increased by extending the conductive material 104 along an additional sidewall of the epitaxial substrate layer 116. For example, as shown in FIG. 4, the trench capacitor 402 may include a first and second capacitor surface that extends continuously along two adjacent sidewalls of the pixel circuit 100b. That is, the trench capacitor 402 extends along two surfaces of an epitaxial substrate layer 116. Using two adjacent sidewalls increases the overall surface area that can be used to form the capacitor, allowing for a higher capacitance than could be achieved by using a single sidewall.

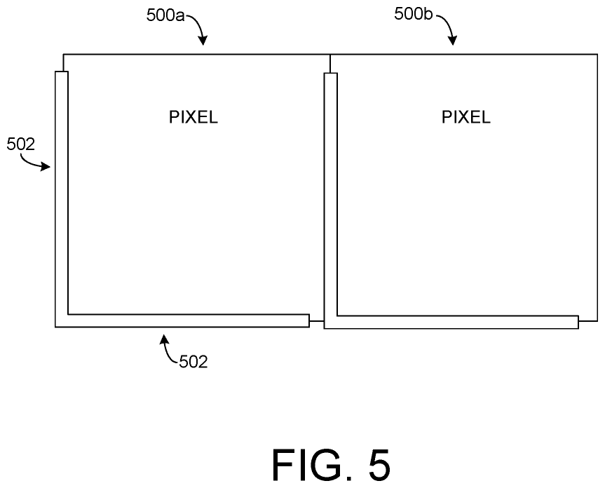

FIG. 5 illustrates a top view of the example of FIG. 4, including a pixel circuit 500a and a pixel circuit 500b. As shown, trench capacitor 502, illustrating an implementation of the trench capacitor 402, extends continuously around two surfaces of an epitaxial substrate layer of the pixel circuit 500a.

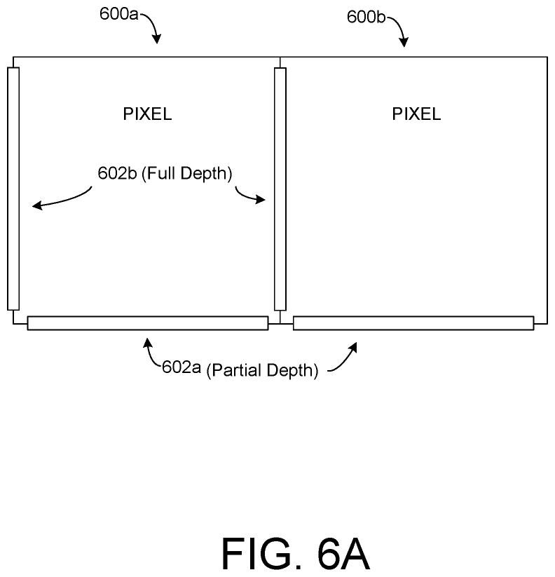

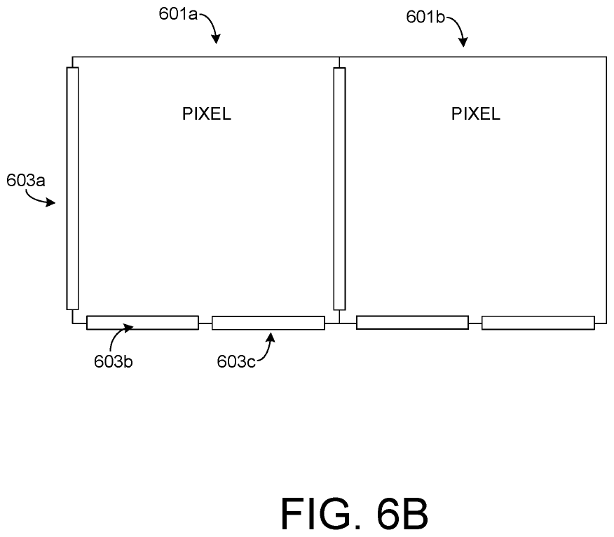

FIG. 6A is a first example top view of the pixels of FIG. 4 with separate deep trench capacitors on each of two walls of each pixel. FIG. 6A illustrates pixel circuit 600a and pixel circuit 600b. As illustrated for the pixel circuit 600a, a first trench capacitor 602a may be formed on a first sidewall, while a second trench capacitor 602b may be formed on a second sidewall. As compared to the continuous trench capacitor 502 of FIG. 5, forming multiple capacitors 602a, 602b on separate sidewalls may increase a total surface area of sidewall structures 120.

Moreover, as referenced above and as also illustrated in FIG. 6A, there may be intra-pixel capacitor differences within a single pixel, while inter-pixel capacitor structures are maintained identically. For example, as shown, the trench capacitor 602a may be a partial depth trench capacitor (as in FIG. 2), while the trench capacitor 602b may be a full depth trench capacitor (as in FIG. 1). Additionally, or alternatively, it is possible that one trench capacitor (e.g., 602a) of a pixel circuit may include the sidewall recesses 120 of FIG. 1, while another trench capacitor (e.g., 602b) of the pixel circuit does not include the sidewall recesses.

FIG. 6B is a second example top view of the pixels of FIG. 4 with separate deep trench capacitors on each of two walls of each pixel. FIG. 6B illustrates pixel circuit 601a and pixel circuit 601b. As illustrated for the pixel circuit 601a, trench capacitor 603a may be formed on a first sidewall, while trench capacitors 603b and 603c may be formed on a second sidewall. Forming multiple trench capacitors 603b, 603c on a sidewall may increase a total surface area of sidewall structures 120, as compared to using a single trench capacitor per sidewall.

FIG. 6B also illustrates that it is possible to include intra-pixel capacitor differences between capacitors on adjacent sidewalls, while maintaining inter-pixel capacitor consistency of an overall capacitor structure. That is, as shown, the adjacent sidewalls of the pixel circuit 601a include the different trench capacitor structures 603a and 603b/603c, while an overall capacitor structure of the pixels 601a, 601b is the same.

Consistent with FIG. 6A, other intra-pixel capacitor differences may be implemented, as well. For example, intra-pixel capacitors may be formed at different depths than one another in FIG. 6B, as well. For example, the trench capacitors 603b, 603c may be formed at a depth that is less than, or greater than, a depth of the trench capacitor 603a. Similarly, with reference back to FIG. 6A, the trench capacitor 602a may be formed at a different (lesser or greater) depth than the trench capacitor 602b. More generally, any of the variations (or other variations) for forming the types of trench capacitors with sidewall structures described herein may be used to form desired types of trench capacitors within a given pixel. For example, a given trench capacitor may be formed with multiple sets of recesses, each set having a different width 122 and/or depth 124 of recesses 120.

For example, implementations with different intra-pixel capacitor depths may be advantageous in certain contexts, such as when constructing global shutter pixel implementations. In such contexts, all sensor pixels are read out simultaneously, and corresponding charge transfer requirements may benefit from having more/larger portions of the epitaxial substrate layer 116 intact. Consequently, maintaining one or more of the trench capacitors in a pixel at a partial depth, perhaps with one or more of the trench capacitors in the pixel at a full depth, may satisfy such charge transfer characteristics.

FIGS. 7-14 illustrate example operations of an example process flow for manufacturing the image sensors of FIGS. 1-6.

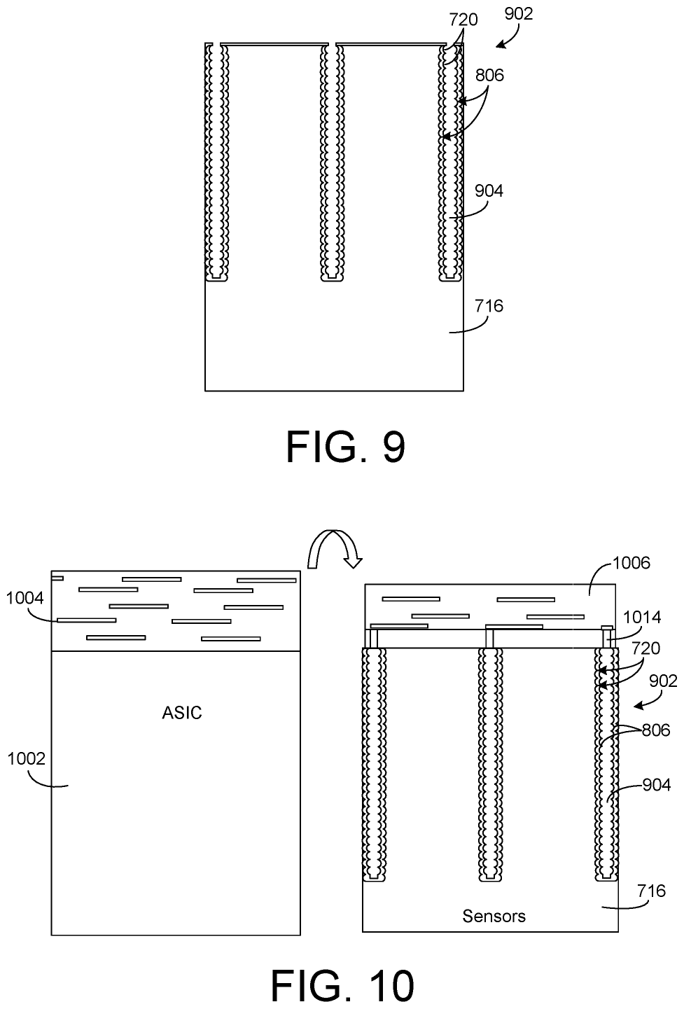

In FIG. 7, an epitaxial substrate layer 716 is illustrated as having trenches 702 formed therein, where the trenches 702 include sidewall recesses 720 along a length thereof, as shown. In FIG. 8, the trenches 702 are filled with insulating material 806. More specifically, for example, a conformal SiO₂ deposition may be performed to form a uniform dielectric layer on the Si surface of the epitaxial substrate layer 716. In FIG. 9, trench capacitors 902 may be defined by filling the trenches 702 with conductive material 904.

Then, in FIG. 10, an ASIC chip 1002 with metal layers 1004 formed thereon may be flip-mounted, e.g., forming a hybrid bond, to metal layers 1006 formed on the epitaxial substrate layer 716. As referenced above with respect to FIGS. 1-3, vias 1014 may be used to connect the trench capacitors 902 to the metal layers 1006. The resulting structure is illustrated in FIG. 11, including a bond line 1102.

For example, a hybrid bond may be used at the bond line 1102, which generally allows for electrical connections to be formed while forming a mechanically stable structure. Hybrid bond pads may be metal, such as copper, nickel, gold, or other suitable metals known in the art. In other implementations, the hybrid bond pads may be made of other non-metal conductive material. A hybrid bond may also be referred to as a direct bond interconnect (DBI).

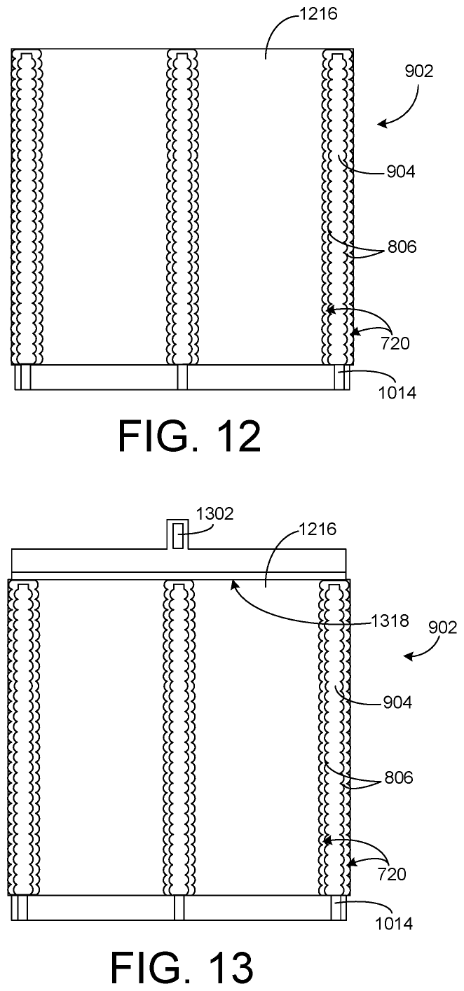

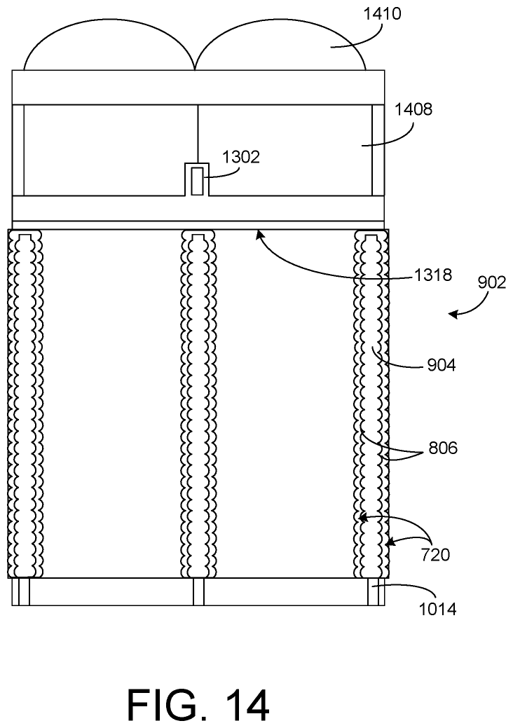

In FIG. 12, in which the ASIC chip 1002 is not shown, the epitaxial substrate layer 716 of FIGS. 7-11 is thinned to obtain an epitaxial substrate layer 1216. In FIG. 13, passivation layer 1318 is added, along with a metal in-pixel grid 1302, e.g., a Tungsten in-pixel grid. In FIG. 14, color filter 1408 and microlens 1410 are added.

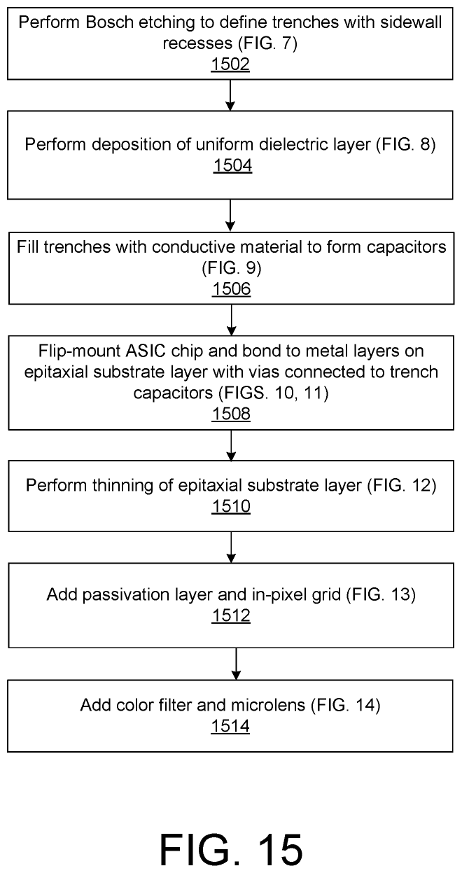

FIG. 15 is a flowchart illustrating example operations for manufacturing the image sensors of FIGS. 1-6, corresponding to the example operations of FIGS. 7-14. At operation block 1502, trenches with sidewall recesses may be formed in the epitaxial substrate layer of a first chip, as shown in FIG. 7 and described above. The first chip may be an image sensor chip. This may include using Bosch etching or other types of etching/masking to define trenches as described herein. At operation block 1504, a dielectric insulating layer may be deposited within the trenches, as shown in FIG. 8 and described above. At operation block 1506, the trenches may be filled with conductive material to form capacitors, or trench capacitors, as shown in FIG. 9 and described above. At operation block 1508, a second chip may be bonded to the first chip, as shown in FIGS. 10-11 and described above. The second chip may be an ASIC chip or other type of chip configured to control elements on the first chip. The bond may be formed between the second chip and metal layers on the epitaxial substrate layer of the first chip with vias connected to the trench capacitors. The metal layers and the vias are formed at a prior step to this bonding step. In some implementations, the second chip is flip-mounted onto the first chip. At operation block 1510, the epitaxial substrate layer may be thinned, as shown in FIG. 12 and described above, so the epitaxial substrate layer has a set thickness with a distance between a first surface and a second surface. The trench capacitors may extend the entire distance or only part of this distance between the first and second surfaces of the epitaxial substrate layer. At operation block 1512, a passivation layer and in-pixel grid may be added, as shown in FIG. 13 and described above. The passivation layer and in-pixel grid may be formed on a surface of the first chip opposite the bonded second chip. At operation block 1514, a color filter and microlens array may be added, as shown in FIG. 14 and described above.

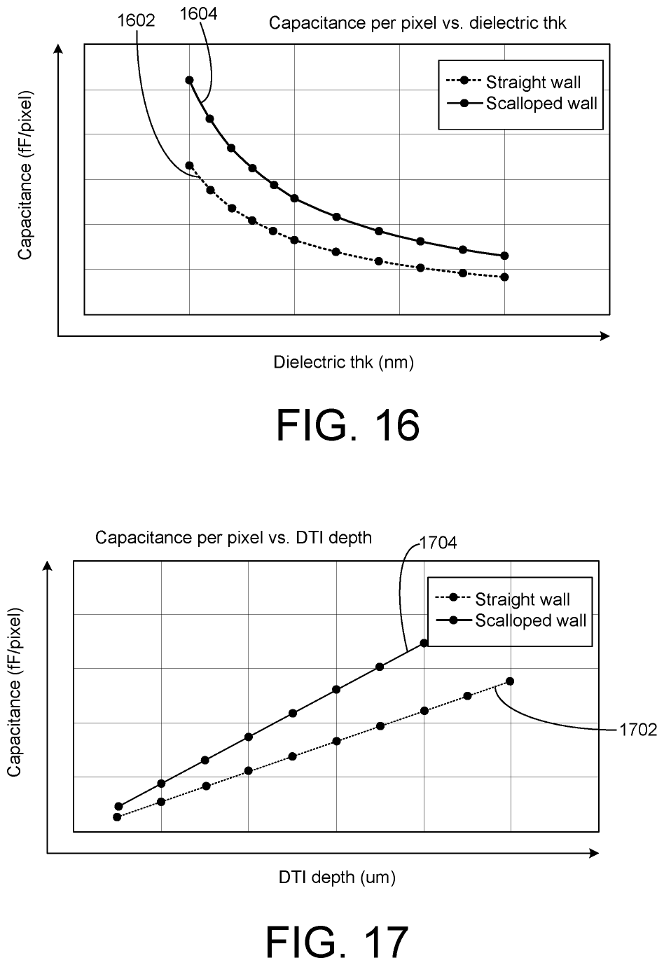

FIG. 16 is a graph illustrating examples of capacitance per pixel versus dielectric thickness for example embodiments. In FIG. 16, a line 1602 indicates example results for a given trench depth with conventional, straight wall trenches. A line 1604 indicates example results for a given trench depth with the sidewall structures described herein. As shown, when using the same insulating/conductive materials and for a given trench depth, described techniques provide capacitive improvements across a range of dielectric thicknesses.

FIG. 17 is a graph illustrating examples of capacitance per pixel versus trench depth for example embodiments. In FIG. 17, a line 1702 indicates example results for a given dielectric thickness with conventional, straight wall trenches. A line 1704 indicates example results for a given dielectric thickness with the sidewall structures described herein. As shown, when using the same insulating/conductive materials and for a given dielectric thickness, described techniques provide capacitive improvements across a range of trench depths.

Described techniques may thus be used to increase a per-pixel capacitance while requiring minimal changes to existing pixel structures, and enabling multiple types of additional advantageous changes to existing pixel structures. For example, for a scallop width 122 in FIG. 1 of “x”, a resulting circumference of π*x/2=1.56x or about a 56% increase in total circumference (e.g., 9.36 um instead of 6 um). Using described techniques, it is possible to achieve capacitances of 200-300 or more femtoFarads per micron square, with corresponding capabilities for 120-140 dB single exposure image capture.

Other implementations are possible, as well. For example, an overall capacitance of a pixel circuit may be increased further by extending the conductive material 104 along not only a second sidewall of the epitaxial substrate layer 116 but also along the upper surface of the epitaxial substrate layer 116 itself. This creates additional surface area over which to form a capacitor, allowing for increased capacitance. Extending the conductive material 104 to the upper surface may require the use of a transparent electrode to prevent photons passing through the microlens 110 and color filter 108 from being blocked from entering the photodetector portion of the pixel circuit 100.

In a first example implementation, referred to herein as Example 1, a semiconductor device comprises:
a microlens;
a color filter disposed adjacent the microlens;
an epitaxial substrate layer disposed adjacent the color filter opposite the microlens; and
a trench capacitor formed in the epitaxial substrate layer and having sidewall recesses.

Example 2 includes the semiconductor device of Example 1, wherein the trench capacitor extends an entire distance of the epitaxial substrate layer.

Example 3 includes the semiconductor device of Example 1, wherein the trench capacitor extends from a surface of the epitaxial substrate layer that is opposite the color filter and only partially through the epitaxial substrate layer.

Example 4 includes the semiconductor device of Example 1, wherein the trench capacitor extends from a surface of the epitaxial substrate layer that is adjacent to the color filter and only partially through the epitaxial substrate layer.

Example 5 includes the semiconductor device of Example 1, wherein the trench capacitor extends along two sidewalls of the epitaxial substrate layer.

Example 6 includes the semiconductor device of Example 1, wherein the trench capacitor is a first trench capacitor and is formed along a first sidewall of the epitaxial substrate layer, and the semiconductor device further comprises:
a second trench capacitor formed along a second sidewall of the epitaxial substrate layer.

Example 7 includes the semiconductor device of Example 6, wherein the sidewall recesses of the first trench capacitor are first sidewall recesses, and the second trench capacitor includes second sidewall recesses in the second sidewall.

Example 8 includes the semiconductor device of Example 6, wherein the first trench capacitor is formed to a first depth within the epitaxial substrate layer and the second trench capacitor is formed to a second depth within the epitaxial substrate layer that is different from the first depth.

Example 9 includes the semiconductor device of Example 1, wherein the trench capacitor is a first trench capacitor and is formed along a sidewall of the epitaxial substrate layer, and the semiconductor device further comprises:
a second trench capacitor formed along the sidewall of the epitaxial substrate layer.

Example 10 includes the semiconductor device of Example 9, wherein the trench capacitor is formed to a first depth within the epitaxial substrate layer and the second trench capacitor is formed to a second depth within the epitaxial substrate layer that is different from the first depth.

In an eleventh example implementation, referred to herein as Example 11, an optical sensor includes an array of pixel circuits, each pixel circuit comprising:
a microlens;
a color filter disposed adjacent the microlens;
an epitaxial substrate layer disposed adjacent the color filter opposite the microlens; and
an isolation trench formed in the epitaxial substrate layer and having sidewalls with sidewall recesses formed therein, the sidewall recesses having insulating material disposed thereon and the isolation trench having a conductive material disposed therein.

Example 12 includes the optical sensor of claim 11, wherein the isolation trench extends only partially through the epitaxial substrate layer in a direction perpendicular to the color filter.

Example 13 includes the optical sensor of Example 11, wherein the isolation trench extends along two sidewalls of the epitaxial substrate layer.

Example 14 includes the optical sensor of Example 11, wherein the isolation trench is a first isolation trench and is formed along a first sidewall of the epitaxial substrate layer, and the optical sensor further comprises:

a second isolation trench formed along a second sidewall of the epitaxial substrate layer.

Example 15 includes the optical sensor of Example 14, wherein the first isolation trench is formed to a first depth within the epitaxial substrate layer and the second isolation trench is formed to a second depth within the epitaxial substrate layer that is different from the first depth.

Example 16 includes the optical sensor of Example 11, wherein the isolation trench is a first isolation trench and is formed along a sidewall of the epitaxial substrate layer, and the optical sensor further comprises:
a second isolation trench formed along the sidewall of the epitaxial substrate layer.

In a seventeenth example implementation, referred to herein as Example 17, a method of making a pixel circuit of an optical sensor comprises:
forming a trench in an epitaxial substrate layer, the trench having sidewall recesses;
providing an insulating material in the sidewall recesses;
providing a conductive material in the trench adjacent to the insulating material;
providing a color filter adjacent to a surface of the epitaxial substrate layer; and
forming a microlens adjacent to the color filter.

Example 18 includes the method of Example 17, further comprising:
forming the trench using a Bosch etching process.

Example 19 includes the method of Example 17, further comprising:
forming the trench along a first sidewall of the epitaxial substrate layer; and
forming a second trench along a second sidewall of the epitaxial substrate layer.

Example 20 includes the method of Example 19, further comprising:
forming the trench to a first depth within the epitaxial substrate layer; and
forming the second trench to a second depth within the epitaxial substrate layer that is different from the first depth.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device, comprising:
a microlens;
a color filter disposed adjacent the microlens;
an epitaxial substrate layer disposed adjacent the color filter opposite the microlens; and
a trench capacitor formed in the epitaxial substrate layer and having sidewall recesses.

2. The semiconductor device of claim 1, wherein the trench capacitor extends an entire distance of the epitaxial substrate layer.

3. The semiconductor device of claim 1, wherein the trench capacitor extends from a surface of the epitaxial substrate layer that is opposite the color filter and only partially through the epitaxial substrate layer.

4. The semiconductor device of claim 1, wherein the trench capacitor extends from a surface of the epitaxial substrate layer that is adjacent to the color filter and only partially through the epitaxial substrate layer.

5. The semiconductor device of claim 1, wherein the trench capacitor extends along two sidewalls of the epitaxial substrate layer.

6. The semiconductor device of claim 1, wherein the trench capacitor is a first trench capacitor and is formed along a first sidewall of the epitaxial substrate layer, and the semiconductor device further comprises:
a second trench capacitor formed along a second sidewall of the epitaxial substrate layer.

7. The semiconductor device of claim 6, wherein the sidewall recesses of the first trench capacitor are first sidewall recesses, and the second trench capacitor includes second sidewall recesses in the second sidewall.

8. The semiconductor device of claim 6, wherein the first trench capacitor is formed to a first depth within the epitaxial substrate layer and the second trench capacitor is formed to a second depth within the epitaxial substrate layer that is different from the first depth.

9. The semiconductor device of claim 1, wherein the trench capacitor is a first trench capacitor and is formed along a sidewall of the epitaxial substrate layer, and the semiconductor device further comprises:
a second trench capacitor formed along the sidewall of the epitaxial substrate layer.

10. The semiconductor device of claim 9, wherein the trench capacitor is formed to a first depth within the epitaxial substrate layer and the second trench capacitor is formed to a second depth within the epitaxial substrate layer that is different from the first depth.

11. An optical sensor including an array of pixel circuits, each pixel circuit comprising:
a microlens;
a color filter disposed adjacent the microlens;
an epitaxial substrate layer disposed adjacent the color filter opposite the microlens; and
an isolation trench formed in the epitaxial substrate layer and having sidewalls with sidewall recesses formed therein, the sidewall recesses having insulating material disposed thereon and the isolation trench having a conductive material disposed therein.

12. The optical sensor of claim 11, wherein the isolation trench extends only partially through the epitaxial substrate layer in a direction perpendicular to the color filter.

13. The optical sensor of claim 11, wherein the isolation trench extends along two sidewalls of the epitaxial substrate layer.

14. The optical sensor of claim 11, wherein the isolation trench is a first isolation trench and is formed along a first sidewall of the epitaxial substrate layer, and the optical sensor further comprises:
a second isolation trench formed along a second sidewall of the epitaxial substrate layer.

15. The optical sensor of claim 14, wherein the first isolation trench is formed to a first depth within the epitaxial substrate layer and the second isolation trench is formed to a second depth within the epitaxial substrate layer that is different from the first depth.

16. The optical sensor of claim 11, wherein the isolation trench is a first isolation trench and is formed along a sidewall of the epitaxial substrate layer, and the optical sensor further comprises:
a second isolation trench formed along the sidewall of the epitaxial substrate layer.

17. A method of making a pixel circuit of an optical sensor, comprising:
forming a trench in an epitaxial substrate layer, the trench having sidewall recesses;
providing an insulating material in the sidewall recesses;
providing a conductive material in the trench adjacent to the insulating material;
providing a color filter adjacent to a surface of the epitaxial substrate layer; and
forming a microlens adjacent to the color filter.

18. The method of claim 17, further comprising:
forming the trench using a Bosch etching process.

19. The method of claim 17, further comprising:
forming the trench along a first sidewall of the epitaxial substrate layer; and
forming a second trench along a second sidewall of the epitaxial substrate layer.

20. The method of claim 19, further comprising:
forming the trench to a first depth within the epitaxial substrate layer; and
forming the second trench to a second depth within the epitaxial substrate layer that is different from the first depth.
